(19) United States
(12) Patent Application Publication
(10) Pub. No.: US 2008/0093722 A1
(43) Pub. Date: Apr. 24, 2008

(54) Encapsulation type semiconductor device and manufacturing method thereof

(76) Inventor: Norihiko Shishido, Kanagawa-ken (JP)

Correspondence Address: SPRINKLE IP LAW GROUP, 1301 W. 25TH STREET, SUITE 408, AUSTIN, TX, 78705, US

(21) Appl. No.: 11/975,539

(22) Filed: Oct. 19, 2007

(30) Foreign Application Priority Data
Oct. 19, 2006 (JP) 2006-285416

(51) Int. Cl. H01L 23/06; H01L 21/56

(52) U.S. Cl. 257/684; 438/127; 257/E21.502; 257/E23.116

(57) ABSTRACT

An encapsulation type semiconductor device and a manufacturing method of the encapsulation type semiconductor device are disclosed. The encapsulation type semiconductor device includes a substrate provided with a concave portion which concaves in a direction from a first principal surface portion to a second principal surface portion. A first semiconductor chip using MEMS is mounted on the concave portion. A first principal surface portion of a second semiconductor chip faces at least the concave portion of the substrate with a space interposed between the first principal surface portion and the concave portion. An outer peripheral side of the concave portion of the first principal surface portion of the substrate is connected with the first principal surface portion of the second semiconductor chip facing the concave portion, by use of a connecting portion.

### CROSS REFERENCE TO RELATED APPLICATION

This application is based upon and claims the benefit of priority from the prior Japanese Patent Application No. 2006-285416, filed on Oct. 19, 2006, the entire contents of which are incorporated herein by reference.

### FIELD OF THE INVENTION

The present invention relates to an encapsulation type semiconductor device encapsulating semiconductor chips and a method of manufacturing the encapsulation type semiconductor device.

### DESCRIPTION OF THE BACKGROUND

Most of semiconductor devices are sensitive to environmental factors, such as contamination or humidity.

In order to protect the semiconductor devices from damages, semiconductor devices are usually encapsulated hermetically using molded resin or ceramic packages.

Among semiconductor devices, micro electromechanical systems (MEMS), high-frequency devices or the like are generally encapsulated hermetically by use of caps made of resin, metal or the like, instead of encapsulating by molded resin, in order to avoid occurrence of characteristic fluctuation and degradation.

Particularly, in the case of the MEMS, extremely fine mechanisms are formed on a surface of a semiconductor. As the MEMS include such extremely fine mechanisms, the MEMS are very easy to suffer damages due to collision of particles, airflows or humidity as compared with other devices.

In recent years, the area of a semiconductor chip such as a system-on-chip (SoC) or a high integration memory to be used in electronic devices has been increased in scale every year, with advance of higher performance, weight reduction and thinning of the electronic devices.

The package for hermetically encapsulating such a semiconductor chip has been provided with multiple pins. Moreover, a plurality of various chips has been housed in a single package. Such a package is called as “system-in-package (SiP)”.

In order to encapsulate systems such as MEMS into a SiP or a wafer level chip scale package (WLCSP), a cap made of resin, metal or the like is used, to render the surrounding of the MEMS chip hollow to prevent damages on the MEMS chip.

Such a structure causes a problem of increase in the number of components. Moreover, the structure also causes a problem of increase in the number of assembling steps, resulting in increase of assembly costs.

### SUMMARY OF THE INVENTION

According to an aspect of an encapsulation type semiconductor device of the invention, an encapsulation type semiconductor device is provided, which includes a substrate including a first principal surface portion, a second principal surface portion opposite to the first principal surface portion and a concave portion, the concave portion concaving in a direction from the first principal surface portion to the second principal surface portion, a first semiconductor chip having MEMS and being mounted on the concave portion, a second semiconductor chip containing a LSI for signal processing, the second semiconductor chip including a first principal surface portion and a second principal surface portion opposite to the first principal surface portion of the second semiconductor chip, the first principal surface portion of the second semiconductor chip facing at least the concave portion with a space interposed, and a connecting portion, which connects an outer peripheral portion surrounding the concave portion of the first principal surface portion of the substrate with part of the first principal surface portion of the second semiconductor chip facing the outer peripheral portion, wherein the first semiconductor chip and the inside of the connecting portion in the first principal surface portion of the second semiconductor chip is encapsulated by the substrate, the second semiconductor chip and the connecting portion.

According to an aspect of a method of manufacturing an encapsulation type semiconductor device of the invention, a method of manufacturing an encapsulation type semiconductor device provided is provided, which includes preparing a substrate including a first principal surface portion having a concave portion and a second principal surface portion opposite to the first principal surface portion, preparing a first semiconductor chip having MEMS and a second semiconductor chip containing a LSI for signal processing, the second semiconductor chip including a first principal surface portion and a second principal surface portion opposite to the first principal surface portion, adhering the first semiconductor chip onto the concave portion, connecting, by use of a connecting portion, an outer peripheral portion surrounding the concave portion in the first principal surface portion of the substrate with part of the first principal surface portion of the second semiconductor chip facing the outer peripheral portion, and encapsulating the first semiconductor chip and the inside of the connecting portion in the first principal surface portion of the second semiconductor chip by the substrate, the second semiconductor chip and the connecting portion.

### BRIEF DESCRIPTION OF THE DRAWINGS

FIG. 1 is a cross-sectional view showing a first embodiment of an encapsulation type semiconductor device according to the present invention.

FIG. 2 is a flowchart showing an example of a method of manufacturing the encapsulation type semiconductor device of FIG. 1.

FIG. 3 is a plan view showing, in a reduced size, a substrate to be used for the encapsulation type semiconductor device of FIG. 1.

FIG. 4 is a cross-sectional view showing a manufacturing step of the encapsulation type semiconductor device of FIG. 1.

FIG. 5 is a plan view showing, in a reduced size, a semiconductor chip to be used for the encapsulation type semiconductor device of FIG. 1.

FIG. 6 is a cross-sectional view showing another manufacturing step of the encapsulation type semiconductor device of FIG. 1.

FIG. 7 is a plan view showing a substrate to be used in a second embodiment of the encapsulation type semiconductor device according to the present invention.

FIG. 8 is a plan view showing a semiconductor chip to be used for the second embodiment.

FIG. 9 is a cross-sectional view showing a third embodiment of the encapsulation type semiconductor device according to the present invention.

FIG. 10 is a plan view showing, in a reduced size, a substrate to be used for the encapsulation type semiconductor device of FIG. 9.

FIG. 11 is a plan view showing, in a reduced size, a semiconductor chip to be used for the encapsulation type semiconductor device of FIG. 9.

FIG. 12 is a cross-sectional view showing a fourth embodiment of the encapsulation type semiconductor device according to the present invention.

FIG. 13 is a flowchart showing an example of the method of manufacturing the encapsulation type semiconductor device of FIG. 12.

FIG. 14 is a plan view showing, in a reduced size, a substrate to be used for the encapsulation type semiconductor device of FIG. 12.

FIG. 15 is a cross-sectional view showing an example of a semiconductor device having MEMS.

### DETAILED DESCRIPTION OF THE INVENTION

Embodiments of the present invention will be described hereinafter with reference to the accompanying drawings.

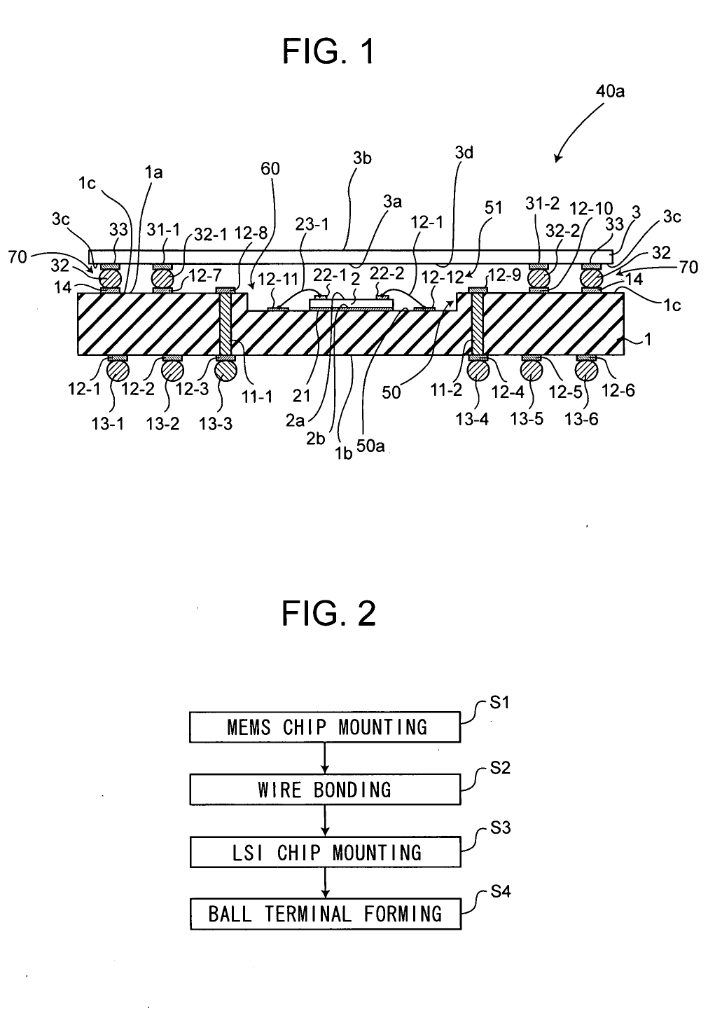

A first embodiment of an encapsulation type semiconductor device and an example of a method of manufacturing the semiconductor device according to the invention will be described with reference to the accompanying drawings. The embodiment is an application of the present invention to a ball grid array (BGA). FIG. 1 is a view showing a cross section of the embodiment.

As shown in FIG. 1, an encapsulation type semiconductor device 40 includes an insulating substrate 1. The substrate 1 includes a first principal surface portion 1a and a second principal surface portion 1b. The second principal surface portion is opposite to the first principal surface portion 1a. A concave portion 50 is formed on the substrate 1. The concave portion 50 concaves in a direction from the first principal surface portion 1a to the second principal surface portion 1b. Connection terminals 12-11 and 12-12 are formed on a bottom portion 50a of the concave portion 50.

A semiconductor chip (a chip using MEMS) 2 serving as a first semiconductor chip is mounted on the concave portion 50 of the substrate 1 with an adhesive layer 21 interposing between the semiconductor chip 2 and the concave portion 50. MEMS are formed in the semiconductor chip 2, as will be described in detail later. The adhesive layer 21 is made of insulation type polyimide resin, for example, and is provided on a central part of the bottom portion 50a of the concave portion 50 of the substrate 1. It is also possible to use insulating resin paste or the like, instead of the insulation type polyimide resin.

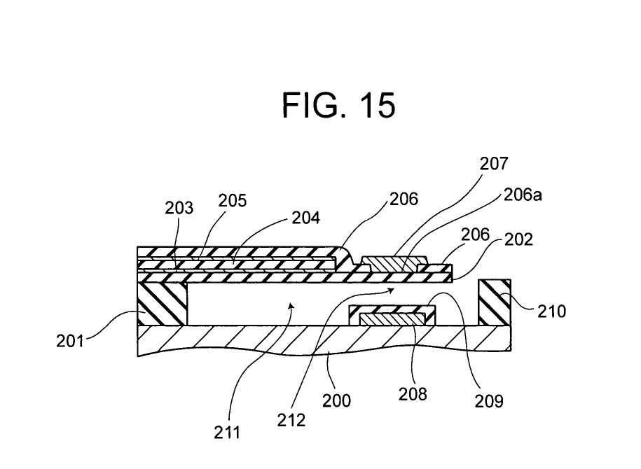

As the semiconductor chip 2, a semiconductor device having MEMS, which is disclosed in United States Patent Application Publication No. 2006/0226735, for example, may be used. The entire contents of the publication are incorporated herein by reference. A semiconductor device having MEMS may also be used which is shown in FIG. 15. In FIG. 15, an insulating anchor 201 is provided on a semiconductor substrate 200. A thin insulating substrate 202 of quartz glass (SiO₂) is hold by the anchor 201. The insulating substrate 202 is capable of bending. An electrode film 203 of platinum is formed on the insulating substrate 202. A piezoelectric film 204 of lead zirconate titanate (PZT) is formed on the electrode film 203. An electrode film 205 of platinum is formed on the piezoelectric film 204. The electrode film 203, the piezoelectric film 204 and the electrode film 205 are laminated. An insulating film 206 of SiO₂ is formed on the electrode film 205 to extend onto a portion of the insulating substrate 202. A hole 206a is formed in the insulating film 206. An electrode 207 of aluminum is formed to cover the hole 206a. An electrode 208 of tungsten is formed on the semiconductor substrate 200 to be opposite against the electrode 207. The electrode 207 is covered with silicon-nitride film 209. A cavity 211 is formed between the semiconductor substrate 200 and the substrate 202. A spatial distance 212 of approximately 1.5 μm exists between the semiconductor substrate 200 and the substrate 202. An insulating member 210, which is apart from the insulating anchor 201, is fixed on the semiconductor substrate 200. The insulating member 210 serves as a wall part to surround the cavity 211. By applying a voltage between the electrode films 203 and 205, the piezoelectric film 204 is bent below in FIG. 15 so that the insulating substrate 202 is bent below. Accordingly, the spatial distance 212 decreases so that the capacitance increases between the electrodes 207 and 208. The change of the capacitance may be used for a tuner or filter. An electric signal may be obtained corresponding to the changed capacitance. The bending of the insulating substrate 202 may be used as a switch. In the embodiment of the invention, an electrostatic type MEMS or thermal type MEMS using expansion and shrinkage by heat may be used for the semiconductor chip 2, in place of the piezoelectric type MEMS as described above.

The semiconductor chip 2 includes a first principal surface portion 2a and a second principal surface portion 2b. The second principal surface portion 2b is opposite to the first principal surface portion 2a. The second principal surface portion 2b is adhered to the adhesive layer 21. The semiconductor chip 2 is apart from the connection terminals 12-11 and 12-12. Chip terminals 22-1 and 22-2 of aluminum (Al) are provided on the first principal surface portion 2a of the semiconductor chip 2. The chip terminals 22-1 and 22-2 are to be connected to the connection terminals 12-11 and 12-12 electrically.

A semiconductor chip (an LSI chip for signal processing) 3, serving as a second semiconductor chip, includes a first principal surface portion 3a facing the first principal surface portion 1a of the substrate 1, and a second principal surface portion 3b opposite to the first principal surface portion 3a. A space is provided between the first principal surface portion 3a and the first principal surface portion 3a.

A belt-like dam 14 is formed on an outer peripheral portion 1c on the first principal surface portion 1a of the substrate 1. The outer peripheral portion 1c surrounds the concave portion 50. The belt-like dam 14 has a loop shape consisting of four sides of a square

A belt-like dam 33 is formed on an outer peripheral portion 3c on the first principal surface portion 3a of the semiconductor chip 3 opposite to the outer peripheral portion 1c. The belt-like dam 33 has a loop shape consisting of four sides of a square. A bump 32, functioning as a dam, is provided between the dams 14 and 33. The dams 14, 33 and the bump 32 constitute a connecting portion 70 collectively. The substrate 1 is attached and fixed to the semiconductor chip 3 by the connecting portion 70.

The semiconductor chip 2 and an inside portion 3d of the connecting portion 70 of the first principal surface portion 3a, which constitutes an inner surface of the semiconductor chip 3, are hermetically encapsulated with a hollow space 60 defined by the substrate 1, the semiconductor chip 3, and the connecting portion 70.

In the encapsulation type semiconductor device 40, having a structure as described above, the semiconductor chip 3 functions as a cap of resin or metal. It is possible to reduce the number of components for preventing characteristic fluctuation and damages of the semiconductor chips 2 and 3, as compared with conventional techniques. Moreover, it is also possible to reduce the number of manufacturing steps. The encapsulation type semiconductor device 40 of the embodiment is compatible with a system-in-package (SiP), a wafer level chip scale package (WLCSP), or the like. Especially, in the case of the semiconductor device with MEMS shown in FIG. 15, the insulating substrate 202 is bent so that the cavity 211 needs to be large. Thus, the semiconductor device 40a is thin due to forming the concave portion 50 in the semiconductor substrate 1 and to providing the semiconductor chip in the concave portion 50. The semiconductor device 40a is thin due to using the semiconductor chip 3 containing the LSI chip for signal processing as a cap, comparing with the case of providing a cap other than the semiconductor chip 3. The semiconductor device 40a is very thin and small as a whole due to the synergy of the semiconductor chip 2 with MEMS formed, the semiconductor chip 3 containing the LSI for signal processing and the concave portion 50.

FIG. 1 will be further described in detail. The substrate 1 is a multilayer substrate made of a glass epoxy substrate, for example. It is also possible to employ a polyimide substrate, a ceramic substrate, or the like as the substrate 1. Connection terminals 12-1 to 12-6 are formed on the second principal surface portion 1b of the substrate 1. The Connection terminals 12-1 to 12-6 are apart from each other. Connection terminals 12-7 to 12-10 are formed on the first principal surface portion 1a of the substrate 1. The connection terminals 12-7 to 12-10 are apart from each other. The connection terminals 12-1 to 12-12 are a copper (Cu) foil, for example. Connection leads 11-1 and 11-2 are Cu, for example, and are buried in the substrate 1. The connection lead 11-1 connects the connection terminal 12-8 to the connection terminal 12-3. The connection lead 11-2 connects the connection terminal 12-9 to the connection terminal 12-4.

Ball terminals 13-1 to 13-6 serving as external terminals are respectively provided on a lower surfaces of the connection terminals 12-1 to 12-6. Chip terminals 31-1 and 31-2 of aluminum (Al) are provided on the first principal surface portion 3a of the semiconductor chip 3. The connection terminal 12-7 is connected to the chip terminal 31-1 of the semiconductor chip 3 through a bump 32-1. The connection terminal 12-10 is connected to the chip terminal 31-2 of the semiconductor chip 3 through a bump 32-2.

Lead (Pb) free solder balls or Au (gold) balls are used as the bumps 32, 32-1, and 32-2, for example. The dams 14 and 33 provided on the substrate 1 and the semiconductor chip 3 respectively can be formed of the same material as the chip terminals 31-1 and 31-2.

The chip terminal 22-1 on the semiconductor chip 2 is connected to the connection terminal 12-11 on the bottom portion 50a of the concave portion 50 of the substrate 1 through a bonding wire 23-1. The chip terminal 22-2 on the semiconductor chip 2 is connected to the connection terminal 12-12 on the bottom portion 50a of the concave portion 50 of the substrate 1 through a bonding wire 23-2. As for the bonding wires 23-1 and 23-2, it is preferable to use bonding wires capable of forming in a low loop shape, in order to keep distances from the first principal surface portion 3a of the semiconductor chip 3.

For example, an electric signal obtained corresponding to the change of the capacitance in the semiconductor chip (the MEMS chip) 2 is inputted to the semiconductor chip (the LSI chip) 3 through the chip terminal 22-1, the connection terminal 12-11, a wire (not illustrated), the connection terminal 12-7, the bump 21-1, and the connection terminal 31-1. An external signal is inputted to the semiconductor chip 3 from outside through the bump 13-5, the connection terminal 12-5, a wire (not illustrated), the connection terminal 12-11, another wire (not illustrated), the connection terminal 12-10, the bump 32-2, and the connection terminal 31-2, for example. When the external signal is inputted, the semiconductor chip 3 executes various kinds of signal processings.

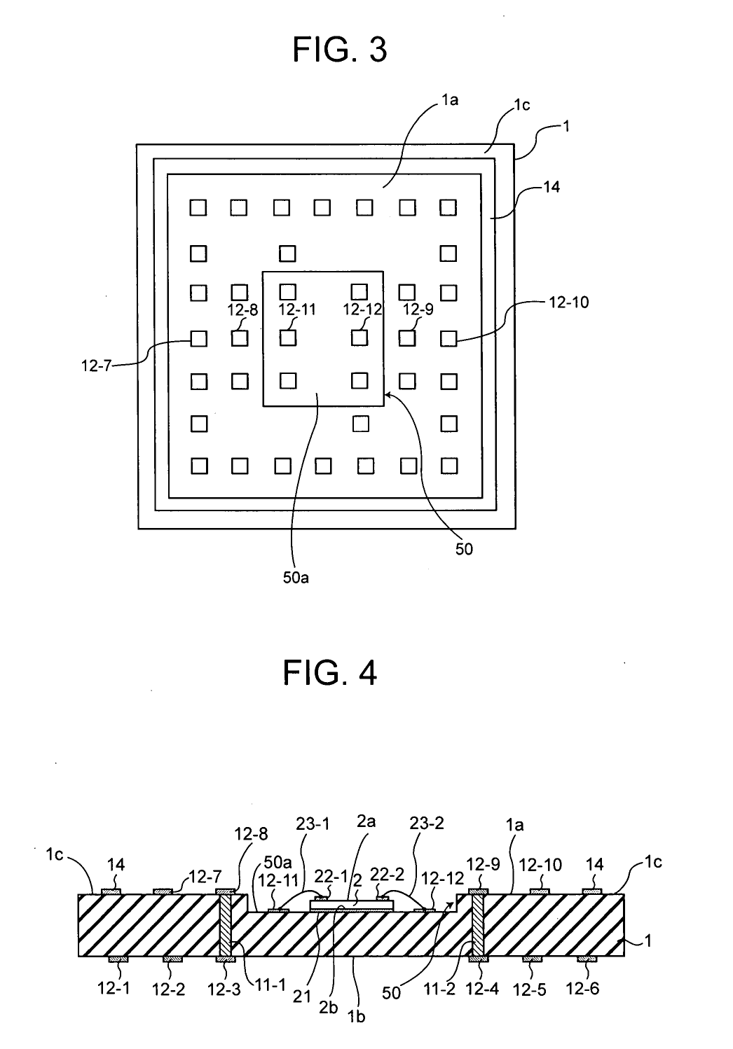

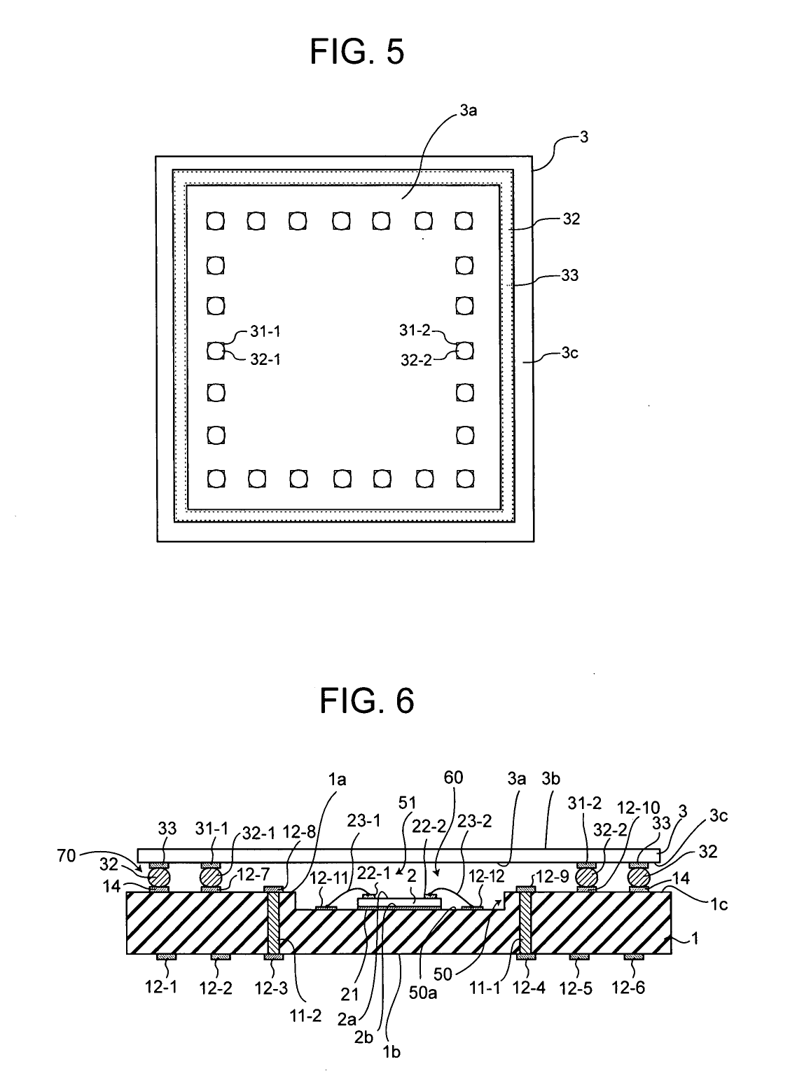

An example of a method of manufacturing the encapsulation type semiconductor device having the configuration shown in FIG. 1 will be described with reference to FIG. 2 to FIG. 6. FIG. 2 is a flowchart showing an example of the manufacturing method of the encapsulation type semiconductor device shown in FIG. 1. FIG. 3 is a plan view showing, in a reduced size, the substrate to be used in the manufacturing method. FIG. 4 is a cross-sectional view showing a step of the manufacturing method. FIG. 5 is a plan view showing, in a reduced size, the semiconductor chip (the LSI chip) to be used in the manufacturing method. FIG. 6 is a cross-sectional view showing another step of the manufacturing method.

The example of the manufacturing method of the encapsulation type semiconductor device shown in FIG. 1 will be described in accordance with FIG. 2. The semiconductor chip (the MEMS chip) 2 in FIG. 1 is attached and fixed to the central part of the concave portion 50 of the substrate 1 by use of the adhesive layer 21 of the insulation type polyimide resin (Step S1). As shown in FIG. 3, the belt-like dam 14 is formed on the outer peripheral portion 1c of the substrate 1. The belt-like dam 14 has a loop shape consisting of four sides of the square. The connection terminals 12-7 to 12-12 and other connection terminals are provided between the dam 14 and the concave portion 50 and on the bottom portion 50a in the concave portion 50. The semiconductor chip (the MEMS chip) 2 is mounted between the connection terminals 12-11 and 12-12 on the concave portion 50a.

As shown in FIG. 4, the chip terminals 22-1 and 22-2 of the semiconductor chip 2 are respectively bonded and connected to the connection terminals 12-11 and 12-12 on the concave portion 50, by use of Au wires capable of forming in a low loop shape, for example (Step S2). The connection may be made by use of bumps, instead of the bonding wires. In this case, the chip terminals 22-1 and 22-2 of the semiconductor chip 2 are respectively connected to the connection terminals 12-11 and 12-12 through the bumps.

As shown in FIG. 5, the belt-like bump 32 is provided on the belt-like dam 33 provided on the outer peripheral portion 3c of the semiconductor chip 3. The belt-like bump 32 and the belt-like dam 33 have a loop shape consisting of four sides of the square. Inside the dam 33, the bumps 32-1 and 32-2 and other bumps are respectively provided on the chip terminals 31-1 and 31-2 and other chip terminals. The chip terminals 31-1 and 31-2 and other chip terminals are apart from the dam 33. The chip terminals 31-1 and 31-2 and the dam 33 are formed simultaneously in a manufacturing process of a semiconductor wafer including the semiconductor chip 3, for example. The bumps 32-1 and 32-2 are formed after completion of manufacturing the wafer including the semiconductor chip 3, for example. After forming the bumps 32-1 and 32-2, the wafer is diced into chips by use of a blade, a laser or the like. When the semiconductor chip 3 is thinned by a lapping technique or the like, it is preferable to remove chipping, damaged layers, fractured layers, and the like in order to improve transverse rupture strength.

Subsequently, as shown in FIG. 6, the semiconductor chip 3 is aligned with the substrate 1 so that the chip terminal 31-1 and the bump 32-1 on the semiconductor chip 3 face the connection terminal 12-7 on the substrate 1, so that the chip terminal 31-2 and the bump 32-2 on the semiconductor chip 3 face the connection terminal 12-10 on the substrate 1, and so that the dam 33 and the bump 32 on the semiconductor chip 3 face the dam 14 on the substrate 1. In the state of alignment as described above, the semiconductor chip 3 is mounted on the substrate 1, and The semiconductor chip 3 is attached and fixed to the substrate 1 by heating (Step S3).

Ball terminals 13-1 to 13-6 of Au bumps are respectively formed on the lower surfaces of the connection terminals 12-1 to 12-6 on the second principal surface portion 1b of the substrate 1 by use of a stud bump bonder, for example.

The ball terminals 13-1 to 13-6 are electrically connected to the connection terminals 12-1 to 12-6 by performing a thermal treatment. Instead of the Au bumps, it is also possible to use lead (Pb) free solder bumps as the ball terminals 13-1 to 13-6, for example (Step S4).

According to the above-described first embodiment of the encapsulation type semiconductor device and the manufacturing method of the semiconductor device according to the present invention, it is possible to make the semiconductor chip 3 have the function of a cap of resin or metal. It is possible to reduce the number of components for preventing characteristic fluctuation and damages of the semiconductor chips 2 and 3, as compared to conventional techniques. Moreover, it is also possible to reduce the number of manufacturing steps.

Although the embodiment is an example of applying the present invention to the BGA, the present invention is also applicable to a land grid array (LGA) with a large-sized semiconductor chip embedded, and the like. The dam 14 formed on the substrate 1 may be buried in the substrate 1 so as to expose only a surface portion of the dam 14, while the dam 33 formed on the semiconductor chip 3 may also be buried in the semiconductor chip 3 so as to expose only a surface portion the dam 33. By employing such a structure, it is possible to improve adhesion strength and peel strength between the substrate 1 and the semiconductor chip 3 to increase reliability of the encapsulation type semiconductor device 40.

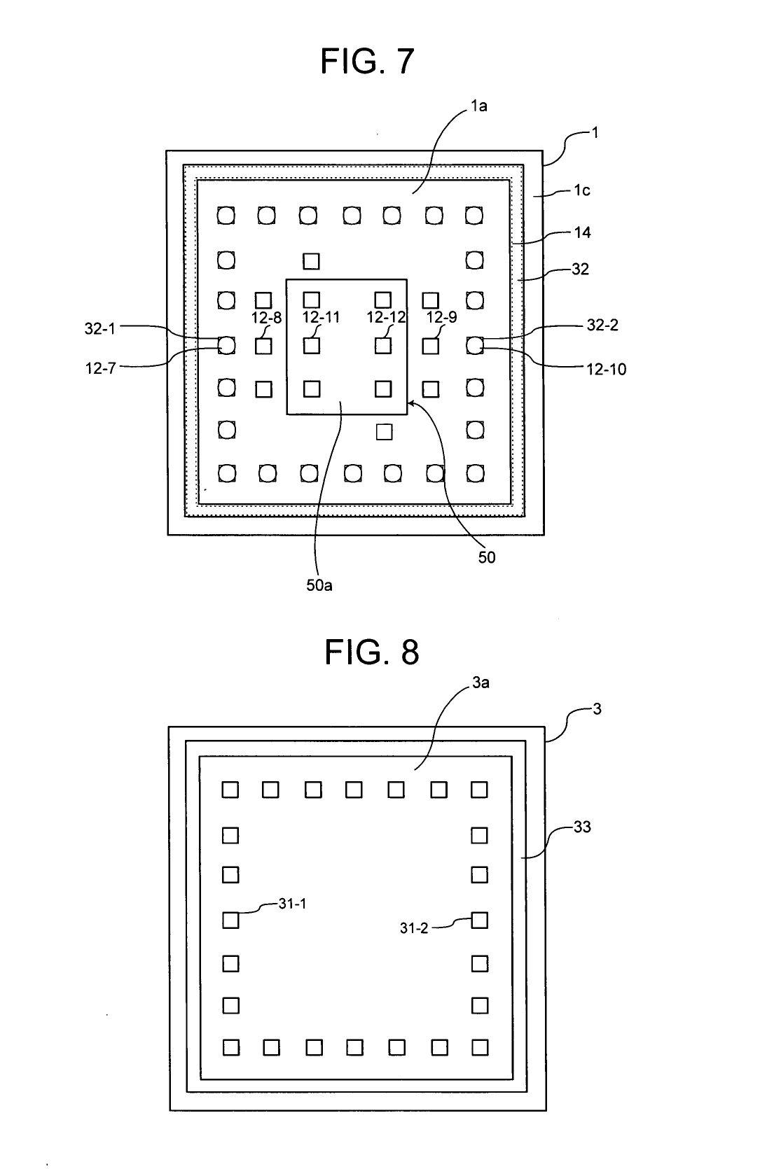

A second embodiment of the encapsulation type semiconductor device according to the present invention will be described with reference to the accompanying drawings. FIG. 7 is a plan view showing a substrate used in this embodiment, and FIG. 8 is a plan view showing the semiconductor chip (the LSI chip) used in this embodiment.

In the following description of the embodiment, the same constituents as those in the first embodiment are designated by the same reference numerals and symbols.

The belt-like dam 14 is formed on the outer peripheral portion 1c of the first principal surface portion 1a of the substrate 1. The belt-like dam 14 has a loop shape consisting of four sides of the square.

The connection terminals 12-7 to 12-12 and other connection terminals are provided in the space between the dam 14 and the concave portion 50 on the bottom portion 50a in the concave portion 50. The bump 32 is provided on the dam 14.

Bumps are respectively provided on the connection terminals 12-7 and 12-10 on the outer peripheral portion 1c. For example, the bump 32-1 is provided on the connection terminal 12-7, and the bump 32-2 is provided on the connection terminal 12-10. The bump 32 that functions as the dam is provided on the dam 14. This embodiment is different from the first embodiment in that the bumps 32, 32-1, and 32-2 are provided on the substrate 1.

On the other hand, as shown in FIG. 8, the dam 33 and the chip terminals 31-1 and 31-2 and other chip terminals are provided on the first principal surface section 3a of the semiconductor chip 3, but no bumps are provided on the first principal surface section 3a.

The encapsulation type semiconductor device of the embodiment can also achieve effects similar to those of the first embodiment.

A third embodiment of the encapsulation type semiconductor device according to the present invention will be described with reference to the accompanying drawings.

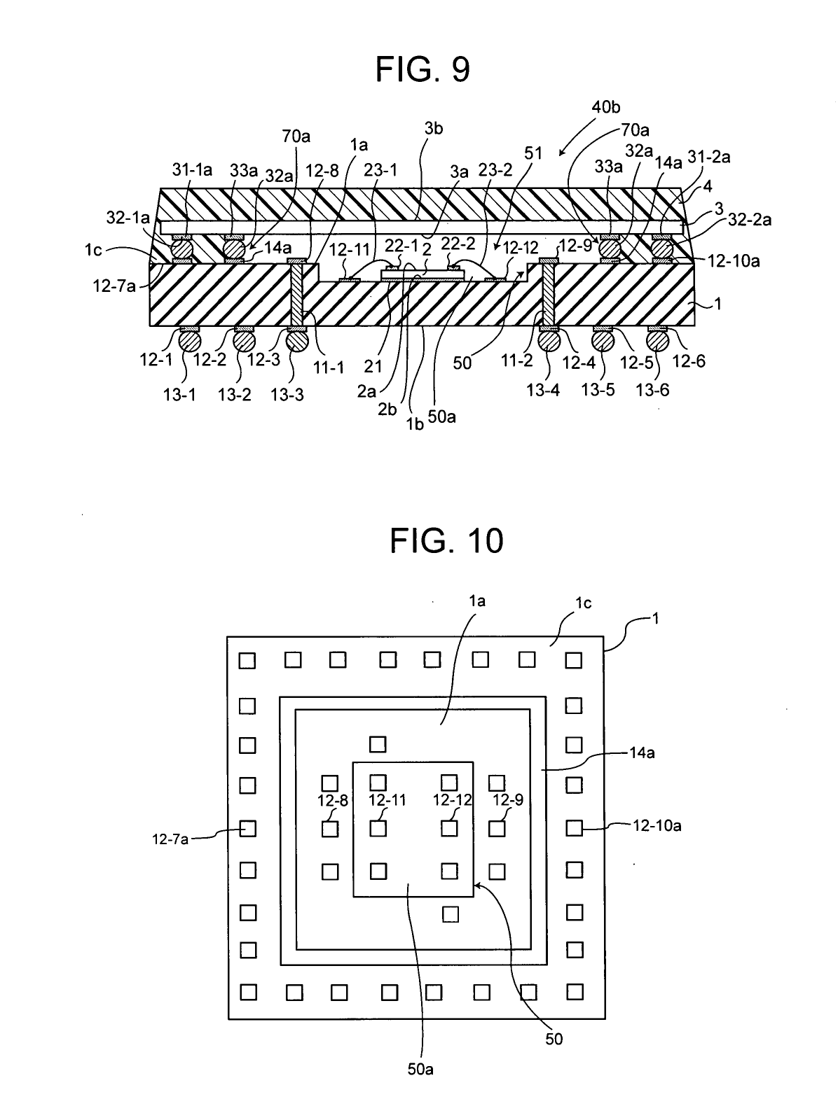

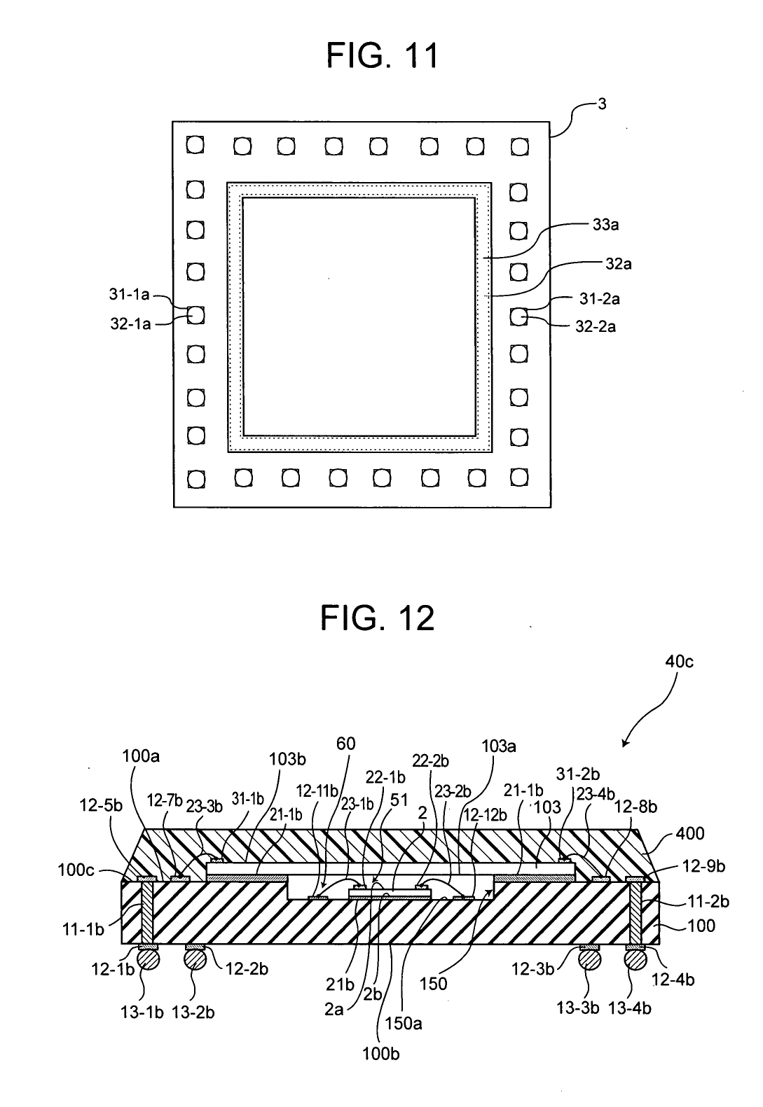

FIG. 9 is a cross-sectional view showing the embodiment of applying the present invention to a BGA (a ball grid array). FIG. 10 is a plan view showing, in a reduced size, a substrate used in this embodiment. FIG. 11 is a plan view showing, in a reduced size, a semiconductor chip in this embodiment.

In the following description of the embodiment, the same constituents as those in the first embodiment are designated by the same reference numerals and symbols respectively.

As shown in FIG. 9 and FIG. 10, in this embodiment, a dam 14a is disposed inside connection terminals 12-7a and 12-10a and other connection terminals on the outer peripheral portion 1c. The embodiment is different from the first embodiment in this regard. Moreover, as shown in FIG. 9 and FIG. 11, a dam 33a and a bump 32a are disposed inside the connection terminals, such as connection terminals 31-1a, 31-2a and other connection terminals and bumps 32-1a and 32-2a and other bumps on the outer peripheral portion 1c in the embodiment. The embodiment is different from the first embodiment in this regard as well.

The dams 14a, 33 and the bump 32a collectively constitute a connecting portion 70a having a loop shape defined by four sides of a square.

Further, unlike the first embodiment, mold resin 4 is provided so as to cover from the outer peripheral portion 1c of the substrate 1 to the second principal surface portion 3b on the backside of the semiconductor chip 3 in the embodiment.

The encapsulation type semiconductor device of the third embodiment can also achieve effects similar to those of the first embodiment.

The mold resin 4 hermetically encapsulates an encapsulation type semiconductor device 40b. Accordingly, it is possible to prevent damages of the semiconductor chip 3 as well as the semiconductor chip 2 more efficiently.

In the embodiment, it is also possible to use a cap made of resin, ceramics or a metal, instead of the mold resin 4.

A fourth embodiment of the encapsulation type semiconductor device and a manufacturing method of the semiconductor device according to the present invention will be described with reference to FIG. 12 to FIG. 14. The embodiment applies the present invention to a BGA. In FIG. 12 to FIG. 14 concerning this embodiment, the same constituents as those in the first embodiment are designated by the same reference numerals and symbols respectively.

FIG. 12 shows a cross section of the encapsulation type semiconductor device of this embodiment.

A substrate 100 is a multilayer substrate made of a glass epoxy substrate, and connection leads 11-1b and 11-2b made of Cu are buried in an outer peripheral portion 100c of the substrate 100, for example. The connection lead 11-1b connects a connection terminal 12-5b formed on a first principal surface portion 100a of the substrate 100 to a connection terminal 12-1b formed on a second principal surface portion 100b of the substrate 100. The connection lead 11-2b connects a connection terminal 12-9b formed on the first principal surface portion 100a of the substrate 100 to a connection terminal 12-4b formed on the second principal surface portion 100b of the substrate 100.

A concave portion 150 is formed on the substrate 100, and the semiconductor chip (the MEMS chip) 2 is attached and fixed onto a bottom portion 150a of the concave portion 150 through an adhesive layer 21b serving as a connecting portion. The adhesive layer 21b is a thin flat layer. Connection terminals 12-11b and 12-12b are formed on the bottom portion 150a so as to be apart from the semiconductor chip 2. Chip terminals 22-1b and 22-2b of the semiconductor chip 2 are connected to the connection terminals 12-11b and 12-12b through boding wires 23-1b and 23-2b.

A semiconductor chip (an LSI chip) 103 is attached and fixed onto the substrate 100 through an adhesive layer 21-1b. The adhesive layer 21-1b is a thin flat layer having a square shape and has a central part corresponding to the concave portion 150 removed. A hermetically encapsulated hollow space is defined by the substrate 100, the adhesive layer 21-1b, and the semiconductor chip 103. In this way, the semiconductor chip (the MEMS chip) 2 is hermetically encapsulated.

For example, an electric signal obtained corresponding to the change of the capacitance in the semiconductor chip 2 is inputted to the semiconductor chip 103 through the chip terminal 22-1b, the connection terminal 12-11b, and a wire (not illustrated). Various kinds of signal processing are executed by the semiconductor chip 103 according to the electric signal.

Ball terminals 13-1b to 13-4b serving as external terminals are respectively provided on lower surfaces of the connection terminals 12-1b to 12-4b formed on the second principal surface portion 100b of the substrate 100. Connection terminals 12-7b and 12-8b formed on the first principal surface portion 100a of the substrate 100 are respectively connected to chip terminals 31-1b and 31-2b through bonding wires 23-3b and 23-4b.

In addition, an external signal is inputted from the ball terminal 13-2b or 13-3b to the semiconductor chip 103 through a wire (not illustrated), for example, and various kinds of signal processing are executed.

For example, an external signal is inputted to the semiconductor chip 103 through the ball terminal 12-1b, the connection lead 11-1b, the connection terminal 12-5b, a wire (not illustrated), the connection terminal 12-7b, and the chip terminal 31-1b, and then, various kinds of signal processing are executed.

Mold resin 400 is provided from above the semiconductor chip 103 to the outer peripheral portion 100c of the substrate 100.

An encapsulation type semiconductor device 40c of the embodiment can also achieve effects similar to those of the first embodiment.

Moreover, in the embodiment, the mold resin 400 is formed from above the second principal surface portion 103b of the semiconductor chip 103 to the outer peripheral portion 100c of the first principal surface portion 100a of the substrate 100. Accordingly, it is possible to prevent damages of the semiconductor chip 103 more effectively than the first embodiment.

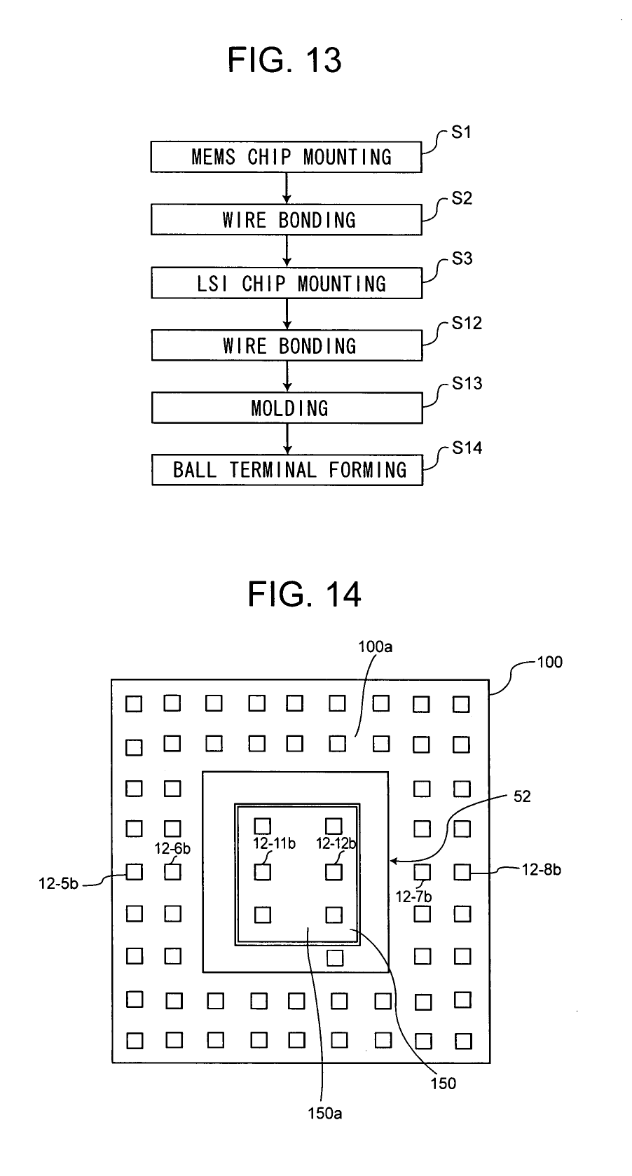

An example of the method of manufacturing the encapsulation type semiconductor device of this embodiment will be described with reference to FIG. 13 and FIG. 14. FIG. 13 is a flowchart showing the example of the method of manufacturing the encapsulation type semiconductor device, and FIG. 14 is a plan view showing, in a reduced size, a substrate used in this embodiment.

In this embodiment, the processes until completion of wire bonding the semiconductor chip 2 are similar to those of the manufacturing method of the first embodiment.

As shown in FIG. 13, the semiconductor chip 103 is mounted on and attached to the first principal surface portion 100a of the substrate 100 (Step S11). Specifically, the adhesive layer 21-1b is provided on an attachment region 52, for the attachment with the semiconductor chip 103, in the outer peripheral portion 100c on a first principal surface portion 103a of the substrate 100 shown in FIG. 14. Then, the first principal surface portion 103a of the semiconductor chip 103 is mounted on and attached to the adhesive layer 21-1b.

The chip terminals 31-1b and 31-2b of the semiconductor chip 103 are connected to the connection terminals 12-7b and 12-8b of the substrate 100 by use of the bonding wires 23-3b and 23-4b (Step S12).

Subsequently, the resin mold 400 is formed so as to cover from the second principal surface portion 103b of the semiconductor chip 103 to the outer peripheral portion 100c of the substrate 100. In this way, the semiconductor chip 103 is encapsulated (Step S13).

The ball terminals 13-1b to 13-4b of Au bumps are respectively formed on the connection terminals 12-1b to 12-4b on the second principal surface portion 100b of the substrate 100 by use of a stud bump bonder, for example. The ball terminals 13-1b to 13-4b are electrically connected to the connection terminals 12-1b to 12-4b, respectively, by performing a thermal treatment (Step S14).

This manufacturing method can also achieve effects similar to those of the method of manufacturing the encapsulation type semiconductor device according to the first embodiment. Moreover, in the embodiment, the mold resin 400 is formed so as to cover from the second principal surface portion 103b of the semiconductor chip 103 to the outer peripheral portion 100c of the substrate 100. Hence, it is possible to prevent damages on the semiconductor chip 103 more effectively than the first embodiment.

It is to be understood that the present invention is not limited only to the above-described embodiments, and various modifications are possible without departing from the scope of the invention.

For example, in the respective embodiments described above, the single semiconductor chip (the LSI chip) is mounted on and attached to the substrate. However, the present invention is not limited only to the configuration. The present invention is also applicable to a SiP or a multi-chip package (MCP). The SiP or the MCP stacks a plurality of semiconductor chips (LSI chips) with an insulating layer interposed between the semiconductor chips, and connects the semiconductor chips to each other by use of a through via hole, for example.

Moreover, in the above-described first to third embodiments of the present invention, the connecting portion has a (single) loop shape defined by four sides of a square. The connecting portion is provided on the substrate to hermetically encapsulate the semiconductor chip (the MEMS chip). Instead, it is also possible to provide a plurality of connecting portions which are mutually symmetrical loop shapes such that a larger loop surrounds a smaller loop, in order to encapsulating the semiconductor chip (the MEMS chip) hermetically.

Further, concerning the semiconductor chip (the MEMS chip) to be provided at the concave portion 50 or 150 of the substrate 1 or 100, it is also possible to hermetically encapsulate a semiconductor chip other than the MEMS chip, such as a microwave monolithic integrated circuit (MMIC) chip to be operated at several 10 G Hz (ten gigahertz).

Other embodiments or modifications of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. An encapsulation type semiconductor device comprising:
a substrate including a first principal surface portion, a second principal surface portion opposite to the first principal surface portion and a concave portion, the concave portion concaving in a direction from the first principal surface portion to the second principal surface portion;
a first semiconductor chip having MEMS and being mounted on the concave portion;
a second semiconductor chip containing a LSI for signal processing and including a first principal surface portion and a second principal surface portion opposite to the first principal surface portion of the second semiconductor chip, the first principal surface portion of the second semiconductor chip facing at least the concave portion with a space interposed; and
a connecting portion, which connects an outer peripheral portion surrounding the concave portion of the first principal surface portion of the substrate with part of the first principal surface portion of the second semiconductor chip facing the outer peripheral portion,
wherein the first semiconductor chip and the inside of the connecting portion in the first principal surface portion of the second semiconductor chip is encapsulated by the substrate, the second semiconductor chip and the connecting portion.

2. The encapsulation type semiconductor device according to claim 1, wherein
a connection terminal is provided on the concave portion, the connection terminal being apart from the first semiconductor chip, and
the connection terminal is electrically connected to a chip terminal of the first semiconductor chip by use of a bonding wire.

3. The encapsulation type semiconductor device according to any one of claim 1, wherein the connecting portion comprises:
a first dam being formed on the first principal surface portion of the substrate;
a second dam being formed on the first principal surface portion of the second semiconductor chip; and
a bump being formed between the first and second dams.

4. The encapsulation type semiconductor device according to claim 3, further comprising:
a mold resin formed extending from the first principal surface portion of the second semiconductor chip to a peripheral portion of the first principal surface portion of the substrate.

5. The encapsulation type semiconductor device according to claim 3,
wherein another connection terminal is formed on part of the first principal surface portion of the substrate, the part being sandwiched between the connecting portion and the concave portion.

6. The encapsulation type semiconductor device according to claim 4,
wherein a connection terminal is formed on part of the first principal surface portion of the substrate, the part being on an outer peripheral side of the connecting portion.

7. The encapsulation type semiconductor device according to any one of claim 1,
wherein the connecting portion is formed of an adhesive layer.

8. The encapsulation type semiconductor device according to claim 7,
wherein another connection terminal is formed on part of the first principal surface portion of the substrate, the part being on an outer peripheral side of the adhesive layer, the connection terminal being electrically connected to a chip terminal of the second semiconductor chip by use of a bonding wire.

9. The encapsulation type semiconductor device according to claim 8, further comprising:
a mold resin extending from the second principal surface portion of the second semiconductor chip to a peripheral portion of the first principal surface portion of the substrate.

10. A method of manufacturing an encapsulation type semiconductor device comprising:
preparing a substrate including a first principal surface portion having a concave portion and a second principal surface portion opposite to the first principal surface portion;
preparing a first semiconductor chip having MEMS and a second semiconductor chip containing a LSI for signal processing, the second semiconductor chip including a first principal surface portion and a second principal surface portion opposite to the first principal surface portion;
adhering the first semiconductor chip onto the concave portion;
connecting, by use of a connecting portion, an outer peripheral portion surrounding the concave portion in the first principal surface portion of the substrate with part of the first principal surface portion of the second semiconductor chip facing the outer peripheral portion;
and encapsulating the first semiconductor chip and the inside of the connecting portion in the first principal surface portion of the second semiconductor chip by the substrate, the second semiconductor chip and the connecting portion.

11. The method of manufacturing an encapsulation type semiconductor device according to claim 10, comprising:
after the first semiconductor chip is adhered to a bottom portion of the concave portion, providing a connection terminal on the concave portion apart from the first semiconductor chip, and
connecting the connection terminal with a chip terminal of the first semiconductor chip electrically by use of a bonding wire.

12. The method of manufacturing an encapsulation type semiconductor device according to any one of claim 10, comprising
providing the connecting portion by forming a first dam on the first principal surface portion of the substrate, by forming a second dam on the first principal surface portion of the second semiconductor chip, and by providing a bump between the first and second dams.

13. The method of manufacturing an encapsulation type semiconductor device according claim 12, comprising:
forming a mold resin so as to extend from the first principal surface portion of the second semiconductor chip to a peripheral portion of the first principal surface portion of the substrate.

14. The method of manufacturing an encapsulation type semiconductor device according to claim 12, comprising
forming another connection terminal on part of the first principal surface portion of the substrate, the part sandwiched between the connecting portion and the concave portion.

15. The method of manufacturing an encapsulation type semiconductor device according to claim 13, comprising
forming another connection terminal on part of the first principal surface portion of the substrate, the portion being on an outer peripheral side of the connecting portion.

16. The method of manufacturing an encapsulation type semiconductor device according to any one of claim 10,
wherein the connecting portion is formed of an adhesive layer.

17. The method of manufacturing an encapsulation type semiconductor device according to claim 16, further comprising
forming another connection terminal on part of the first principal surface portion of the substrate, the part being on an outer peripheral side of the adhesive layer, and
connecting the connection terminal with a chip terminal of the second semiconductor chip electrically by use of a bonding wire.

18. The method of manufacturing an encapsulation type semiconductor device according to claim 17, comprising
forming a mold resin so as to extend from the second principal surface portion of the second semiconductor chip to a peripheral portion of the first principal surface portion of the substrate.
